(19) United States
(12) Patent Application Publication
(10) Pub. No.: US 2006/0276034 A1
(43) Pub. Date: Dec. 7, 2006

(54) Forming via contacts in MRAM cells

(76) Inventor: Philippe Blanchard, Moigny sur Ecole (FR)

Correspondence Address: EDELL, SHAPIRO & FINNAN, LLC, 1901 RESEARCH BOULEVARD, SUITE 400, ROCKVILLE, MD, 20850, US

(21) Appl. No.: 11/145,180

(22) Filed: Jun. 6, 2005

(51) Int. Cl. H01L 21/44

(52) U.S. Cl. 438/672

(57) ABSTRACT

A method of forming a via contact in the manufacture of a magnetoresistive memory cell includes providing a semiconductor substrate including at least one metallic region made of metallic material formed upon a main surface of the substrate. A first layer made of first non-conductive material is deposited at least on the metallic region, and a second layer of second non-conductive material is deposited at least on the first layer of first non-conductive material. The second non-conductive material has an etch-selectivity in relation to the first non-conductive material. The second layer is patterned, where a portion of the first layer is exposed, and polymer residuals created in patterning of the second layer are removed. The exposed portion of the first layer is selectively etched, where a portion of the metallic region is exposed. A layer of conductive material is deposited at least on the exposed portion of the metallic region, followed by a planarization of the conductive material to form the via contact on the metallic region.

### FIELD OF THE INVENTION

The present invention relates to non-volatile semiconductor memory chips and more particularly relates to methods of forming via contacts in the manufacture of magnetoresistive random access memory cells (MRAM cells) for use in a semiconductor integrated circuit.

### BACKGROUND

Strong efforts have been made in the semiconductor industry to bring into practical use a new promising memory technology based on non-volatile MRAM cells. An MRAM cell includes a stacked structure of magnetic layers separated by a non-magnetic tunneling barrier layer or, alternatively, a conductive barrier layer. In the former case, a magnetoresistive tunnel junction (MTJ) memory cell is formed. In the latter case, a giant magnetoresistive memory cell is formed. As used herein, and as is conventionally recognized when referring to the published references in the art relating to such devices, the MTJ memory cell and the giant magnetoresistive memory cell are encompassed by the terms “magnetoresistive memory cell” and “magnetoresistive element.”

In MRAM cells, digital information is not maintained by power as in conventional DRAMs, but rather by directions of magnetizations in the ferromagnetic layers. More specifically, in an MRAM cell, magnetization of one ferromagnetic layer (“reference layer” or “pinned layer”) is magnetically fixed or pinned, while magnetization of the other ferromagnetic layer (“free layer”) is free to be switched between two preferred directions along an easy axis of magnetization thereof, which typically is in parallel alignment with the reference layer fixed magnetization.

Depending upon the magnetic orientation of the free layer, an MRAM cell exhibits two different resistance values in response to a voltage applied across the MRAM cell, where the resistance thereof is “low” when magnetizations are in parallel alignment and “high” when magnetizations are in antiparallel alignment. Accordingly, logic values (“0” and “1”) may be assigned to different magnetizations of the free layer, and detection of electric resistance provides the logic information stored in the magnetic memory element. An MRAM cell typically is written to through application of magnetic fields created by bi- or unidirectional currents made to run through conductive lines operatively located adjacent the MRAM cell so that magnetic fields thereof can be coupled to the free layer magnetization.

In accordance with the well-known standard CMOS process for manufacturing MRAMs, upon a silicon or other suitable substrate that is provided with active substrate devices such as transistors and the like, via contacts and metallization layers are formed to provide interconnections for the integrated circuit and the magnetoresistive memory cell array. Interconnections typically are formed by providing dielectric layers, masking and etching thereof, as well as metal deposition, all in a well-known manner. In accordance with the standard CMOS process, the metallization layer forming the first layer of interconnects is referred to as the first metallization layer (M1), and via contacts formed on the first metallization layer M1 in a layer of dielectric material are referred to as the first via layer (V1). The next metallization layer formed in a layer of dielectric material is referred to as the second metallization layer (M2), followed in sequence by a second via layer (V2) formed in a layer of dielectric material, a third metallization layer (M3) formed in a layer of dielectric material, and so on to provide as many via layers and metallization layers as are needed for the specific apparatus and application. Final via contacts (VB) formed in a layer of dielectric material are provided for connecting of magnetic tunnel junctions (MTJs) formed thereupon.

Conventionally, in the preparation of via contacts for interconnecting different metallization layers or connecting of MTJs, through-holes (vias) are etched into dielectric material in a single etch step, followed by depositing of conductive material and planarizing thereof for instance using CMP (chemical-mechanical polishing) to thereby form the conductive via contacts.

However, in such conventional manufacturing of via contacts, a problem arises where, as etching proceeds, polymer residuals are likely to be deposited on the via walls and also on opened conductive material of the metallization layer located below. Polymer resisuals may also be embedded in later process steps and can cause severe problems as to an outgassing thereof or modification or creation of interface layers. Also, with respect to following etch processes, for instance using chlorine as etch agent, weak points are created on the via walls with polymer residuals applied thereupon to then result in a rather uneven etch attack.

Accordingly, due to the problems noted above, polymer residuals that are to be removed cannot be removed easily without risking damage or at least degradation of the metallic material of the opened metallization layer.

### SUMMARY

In light of the above, it is an object of the invention to provide an improved method of manufacturing MRAM cells that allows removal of polymer residuals in the formation of via contacts without risking damage or degradation of metallic material.

The above and further objects are achieved in accordance with the present invention. In an exemplary embodiment of the invention, a method of forming a via contact on a metallic region in the manufacture of a magnetoresistive memory cell comprises: providing a semiconductor substrate including active structures (such as transistors and the like) and including at least one metallic region made of metallic material formed upon a main surface thereof; depositing a first layer made of a first non-conductive material at least on (over) the metallic region using a suitable deposition technique (e.g., chemical vapor deposition or CVD); depositing a second layer made of second non-conductive material at least on (over) the first layer of first non-conductive material using a suitable deposition technique (e.g., CVD), where the second non-conductive material has an etch-selectivity in relation to the first non-conductive material such that the first layer acts as an etch stop layer with respect to the second layer; patterning of the second layer, wherein a portion of the first layer is exposed, via lithography and etch steps that create polymer residuals; removing the polymer residuals created in patterning of the second layer; selectively etching the exposed portion of the first layer, wherein a portion of the metallic region is exposed; and depositing a layer of conductive material at least on the exposed portion of the metallic region, followed by a planarization of the conductive material to form the via contact on the metallic region.

Preferably, the method further comprises: depositing a third layer of third non-conductive material at least on the second layer of the second non-conductive material, where the third non-conductive material has an etch-selectivity in relation to the second non-conductive material such that the second layer acts as etch stop layer with respect to the third layer; and patterning the third layer using a photosensitive layer, wherein a portion of the second layer is exposed.

In embodiments where the third layer is applied to the second layer, removal of the photosensitive layer used for patterning the third layer is achieved along with removal of the polymer residuals.

The first and third non-conductive materials can be the same material. Preferably, first and third non-conductive materials are selected from the group consisting of silicon nitride, silicon oxide and silicon carbide.

The second non-conductive material, which is different from the first and third non-conductive materials, preferrably is selected from the group consisting of silicon nitride, silicon oxide and silicon carbide.

In addition, the second layer preferably has a thickness in a range of about 30 nm to about 60 nm. This second layer thickness range is preferable due the etch process uniformity and etch selectivity between first, second and third materials.

The above and still further objects, features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 schematically depicts schematically a cross-sectional side view in elevation of an intermediate product in the manufacture of MRAM cells.

FIGS. 2A to 2Q schematically depict cross-sectional side views in elevation of intermediate products formed in a sequence of process steps for manufacturing MRAM cells according to the invention.

### DETAILED DESCRIPTION

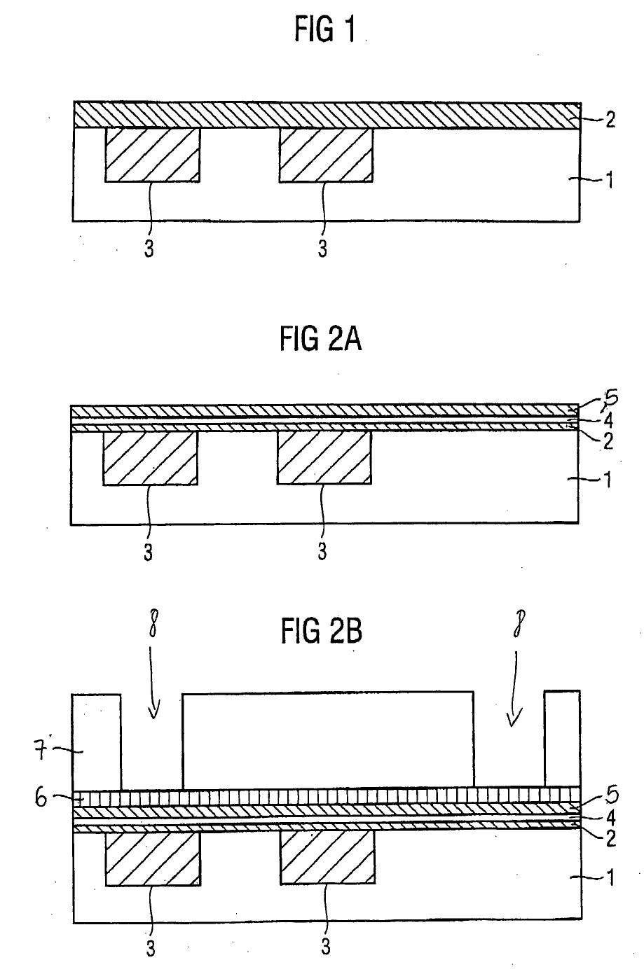

Referring to FIG. 1, a cross-sectional side view is depicted of an intermediate product formed in a conventional method for manufacturing MRAM cells. In a layer of dielectric material, such as silicon oxide, conductive lines 3 made of metallic material, such as copper (Cu), are formed to create a metallization layer 1 (M1). On the metallization layer (M1), a layer 2 made of silicon nitride (SiN) is deposited, which may also be a tri-layered structure including SiN, UVSiN (i.e. SiN with better conformality) and SiN. In the formation of via contacts enabling electric contact from above to the metallic lines 3, the SiN-layer 2 typically is etched in a single etch step. This single etch step is likely to create polymer residuals on the via walls and on the opened Cu metallic lines 3, which in turn may cause problems in further processing.

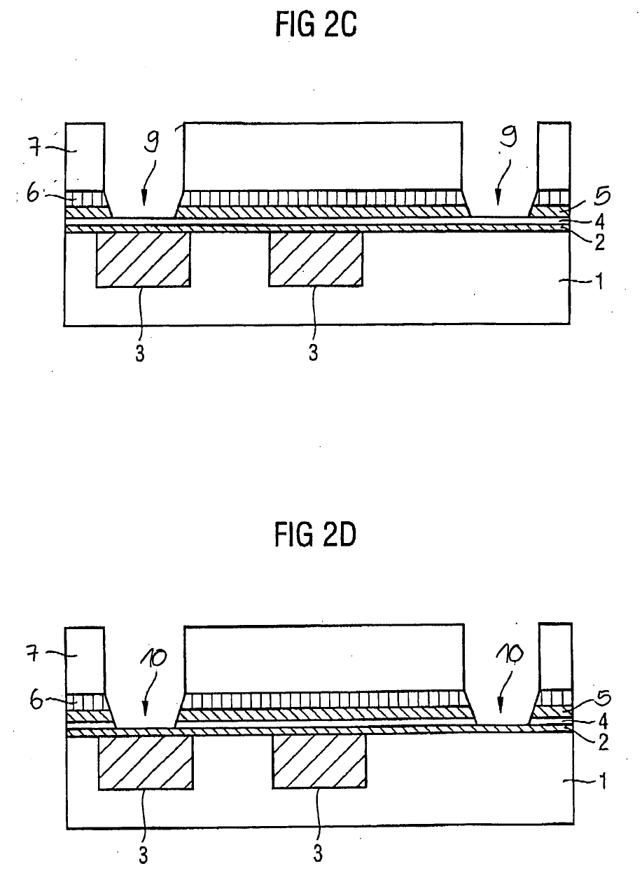

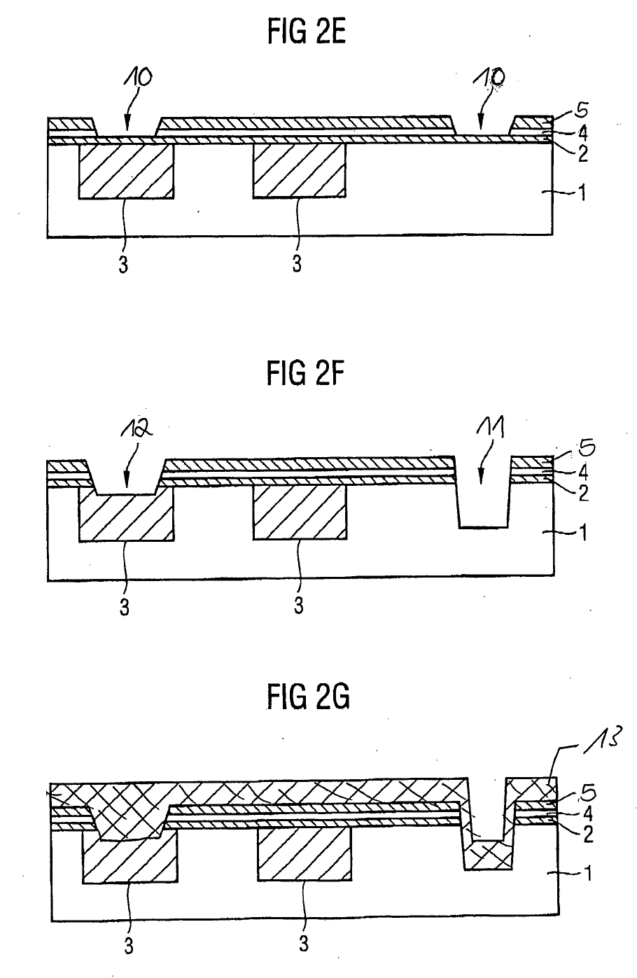

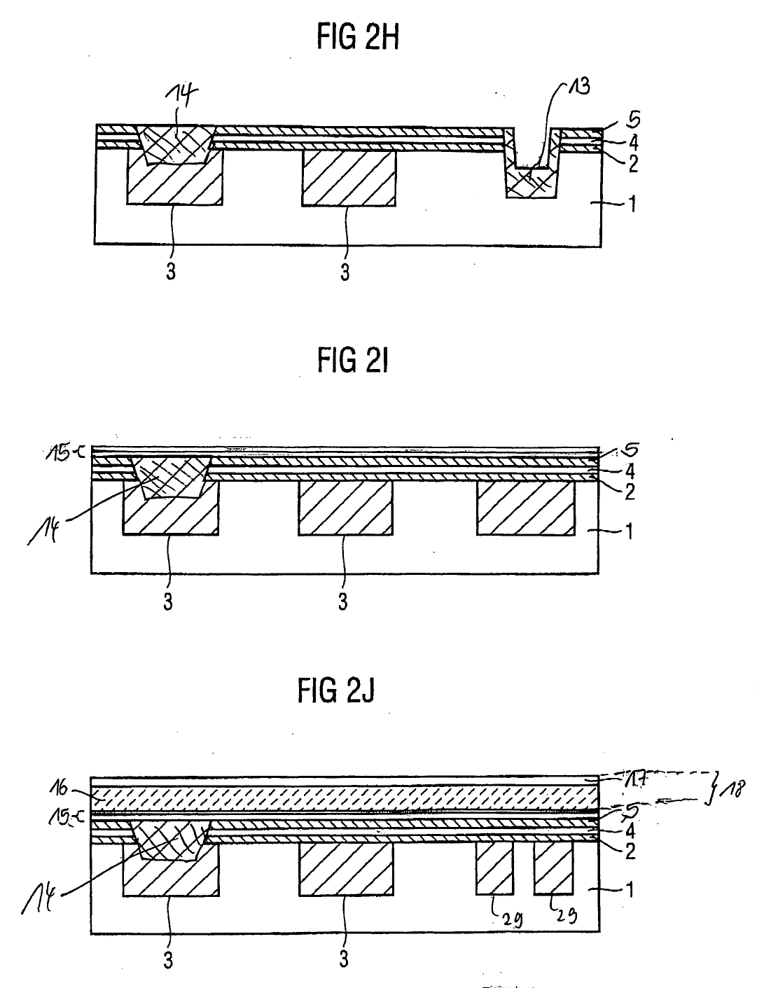

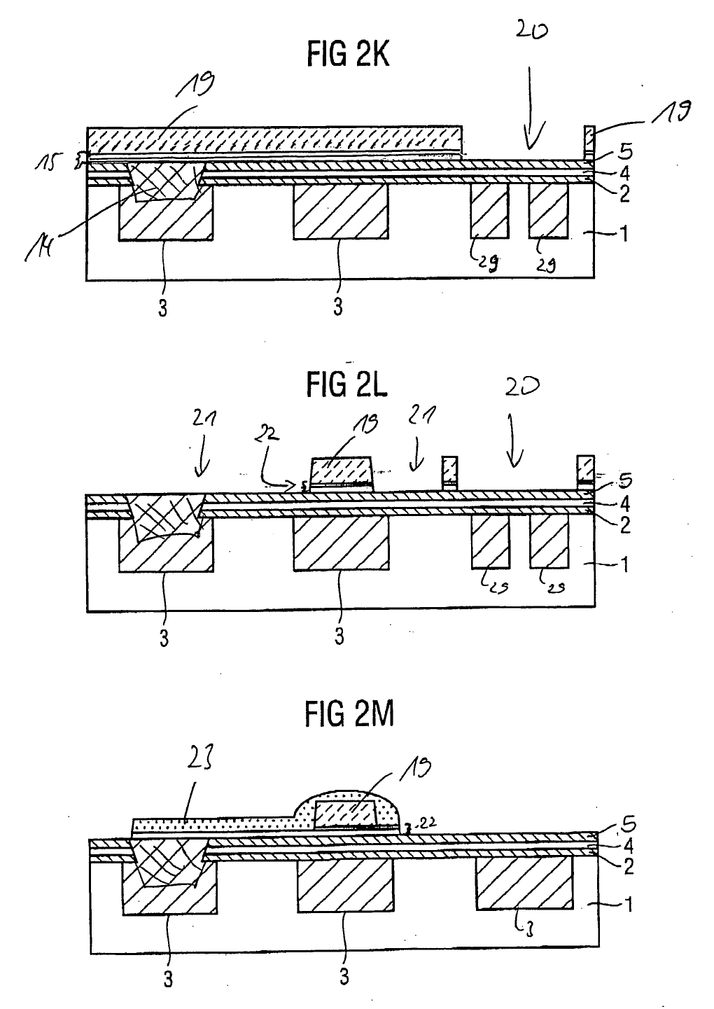

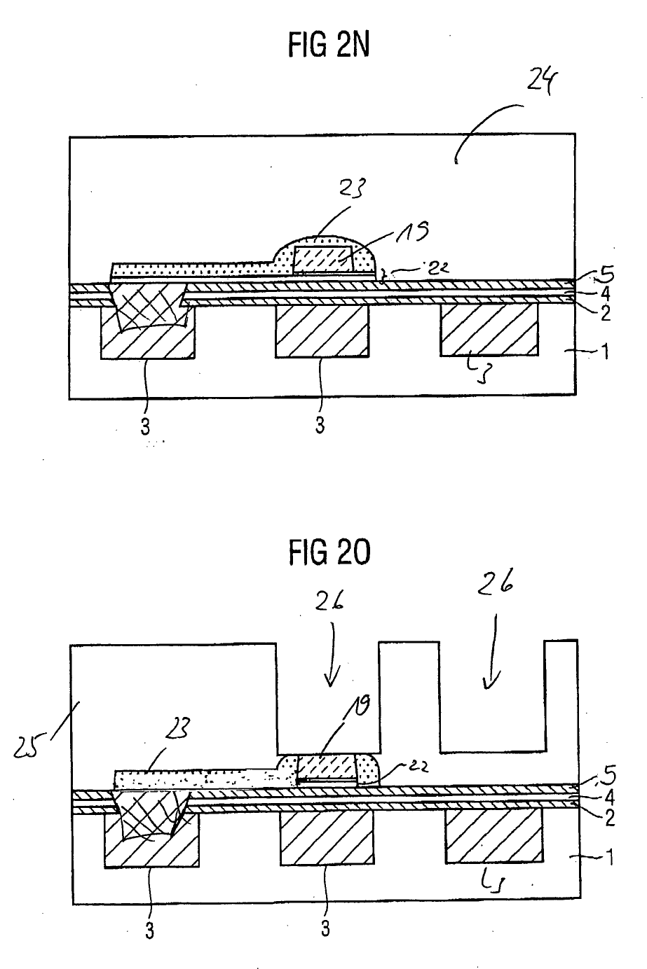

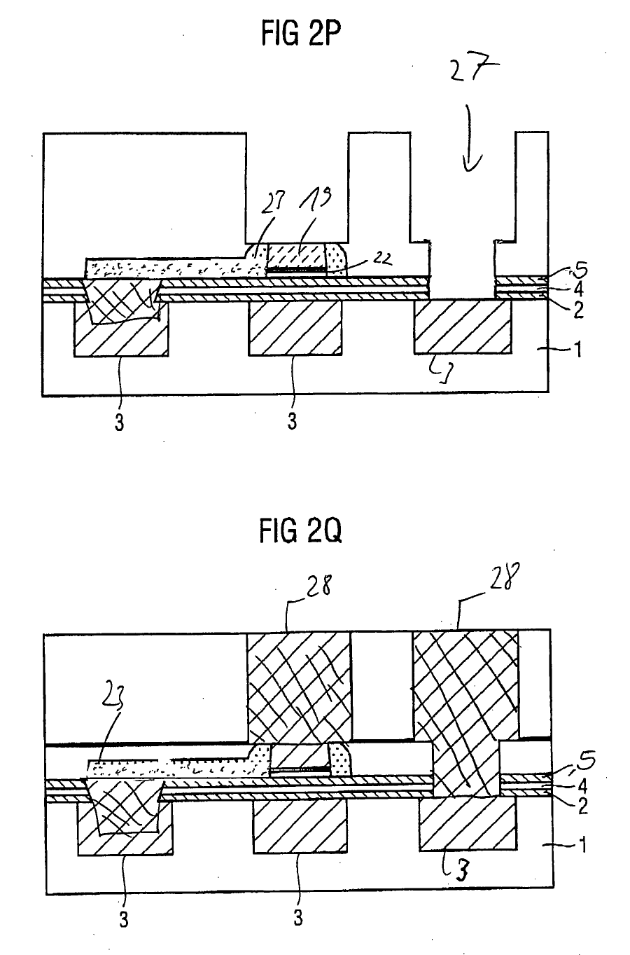

Referring now to FIGS. 2A to 2Q, a process sequence of manufacturing MRAM cells according to the invention is described. In particular, a layer of dielectric material, such as silicon oxide, metallic lines 3 made of conductive material, such as copper (Cu), are formed to create metallization layer 1 (M1). On the metallization layer, a tri-layered structure including a bottom layer 2 made of SiN, an intermediate layer 4 made of silicon carbide (SiC) and a top layer 5 made of SiN is formed (as depicted in FIG. 2A). The intermediate layer preferably has a thickness in a range of about 30 nm to about 60 nm.

On the tri-layered structure 2, 4, 5, an anti-reflective layer 6 is deposited, followed by depositing a photosensitive (resist) layer, which is patterned to form a resist layer mask 7 having openings 8 using a conventional or other suitable patterning technique (as depicted in FIG. 2B).

Using the resist layer mask 7, the anti-reflective layer 6 and the top layer 5 made of SiN are etched in a single etch step to create openings 9, where etching stops on the intermediate layer 4 (made of SiC) thus functioning as etch stop layer using etch-selectivity of SiN- and SiC-layers which, for instance, may amount to 15:1. For etching thereof, any convenient etching technique may be used. For example, an etching technique may be used using CH₃F and O₂ etch gases. The resultant intermediate product is depicted in FIG. 2C.

Intermediate layer 4 (made of SiC) is then etched, where etching stops on the bottom layer 2 (made of SiN) such that the bottom layer functions as an etch stop layer. In particular, the etch-selectivity of the SiC- and SiN-layers results in the formation of openings 10 (as depicted in FIG. 2D) as a result of this etching step. For etching, any convenient etching technique may be used such as, for example, a technique that makes use of CH₃F, O₂ and N₂ etch gases.

Next, both the resist layer mask 7 and the anti-reflective layer 6 are removed (as depicted in FIG. 2E) using any conventional or other suitable stripping technique. The stripping is achieved before conductive lines 3 are opened, such that no copper oxidation and no polymer formation on conductive lines 3 can occur.

Stripping of the resist layer mask 7 is followed by two etch steps. A first etch step is carried out to etch the bottom layer 2 (made of SiN) that stops on the silicon oxide layer 1 using etch selectivity of SiN- and SiO-layers (e.g., using an etch process with CH₃F and O₂ etch gases) to create opening 12 (as depicted in FIG. 2F). A second etch step is then carried out to etch oxide layer 1 using etch selectivity to SiN (e.g., using an etch process with C₃F₈, CO and O₂ etch gases) to create opening 11 (FIG. 2F).

A conductive layer 13 made of conductive material, such as TaN, is then deposited using any conventional or other suitable deposition technique (as depicted in FIG. 2G). The conductive layer is then planarized using, e.g., a chemical-mechanical polishing (CMP) technique, to create conductive TaN-structures 14 (FIG. 2H).

On the planarized surface, a layered structure 15 is deposited (FIG. 2I). The layered structure 15 includes a ferromagnetic bottom layer, a non-conductive tunneling barrier or conductive intermediate layer and a ferromagnetic top layer, to create magnetoresistive elements. A layered hard mask 18 is then deposited on the layered structure 15 (FIG. 2J), where the layered hard mask includes a titanium nitride layer 16 and an oxide layer 17. As can be seen in FIG. 2J, metallic alignment marks 29 are shown in layer 1 which are used in the next lithography step.

Conventional or other suitable lithography and etch steps are used to open the layered hard mask 18 to create patterned hard mask 19, followed by selective etching that stops on top SiN-layer 5 to create opening 20 (as depicted in FIG. 2K), such that the next lithography step is properly aligned.

Further lithograpy and etch steps are carried out to create openings 21 for forming of a magnetoresistive elements 22 pattern (FIG. 2L), followed by depositing a dielectric layer (e.g., made of oxide) that is patterned using conventional or other suitable lithography and etch steps to create a patterned dielectric layer 23 (FIG. 2M). As depicted in FIG. 2M, only metallic lines 3 are visible in layer 1.

A thick dielectric layer 24 made of oxide (e.g., silicon oxide) is deposited on the magnetoresistive elements pattern, followed by a planarization thereof, to protect the MTJs (FIG. 2N).

Oxide layer 24 is then patterned using conventional or other suitable lithography and etch steps to create patterned oxide layer 25 having openings 26, at least one of which uncovers the TiN-layer remnant 19 on top of the magnetoresistive element 22 (FIG. 2O).

Further lithography and etch steps are then carried out, where etching stops on metallic line 3 to create opening 27 to establish electric contact between upper and lower metal lines (FIG. 2P).

Finally, metallic material 28, such as copper, is deposited, followed by a planarization therof, for instance using chemical-mechanical polishing (CMP), to complete the metallization level (FIG. 2Q).

While processng of only one via contact has been demonstrated in the method described above, the invention is not limited to processing one via contact. Rather, the methods of the invention include processing of a plurality of via contacts and MRAM cells.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### REFERENCE LIST

1 Metallization layer (M1)
2 SiN-layer
3 Metallic line
4 SiC-layer
5 SiN-layer
6 Anti-reflective layer
7 Resist layer mask
8 Opening
9 Opening
10 Opening
11 Opening
12 Opening
13 Conductive TaN-layer
14 Conductive TaN-structures
15 Layered structure
16 TiN-layer
17 Oxide layer
18 Hard mask
19 Patterned hard mask
20 Opening
21 Opening
22 Magnetoresistive element
23 Patterned dielectric layer
24 Dielectric layer
25 Patterned dielectric layer
26 Opening
27 Opening
28 Metallic material
29 Metallic alignment mark

What is claimed is:

1. A method of forming a conductive via contact on a metallic region in the manufacture of a magnetoresistive memory cell, the method comprising:
providing a semiconductor substrate including at least one metallic region comprising a metallic material formed on a surface of the substrate;
depositing a first layer comprising a first non-conductive material at least on the metallic region;
depositing a second layer comprising a second non-conductive material at least on the first layer, wherein the second non-conductive material has an etch-selectivity in relation to the first non-conductive material;
patterning of the second layer, wherein a portion of the first layer is exposed;
removing polymer residuals that have been created in patterning of the second layer;
selectively etching the exposed portion of the first layer, wherein a portion of the metallic region is exposed;
depositing a layer of conductive material at least on the exposed portion of the metallic region; and
planarizing the layer of conductive material to form a via contact on the metallic region.

2. The method of claim 1, further comprising:
depositing a third layer comprising a third non-conductive material at least on the second layer, wherein the third non-conductive material has an etch-selectivity in relation to the second non-conductive material; and
patterning the third layer, wherein a portion of the second layer is exposed.

3. The method of claim 2, wherein the third layer is patterned using a photosensitive layer.

4. The method of claim 3, wherein polymer residuals are removed along with removal of the photosensitive layer.

5. The method of claim 2, wherein the first and third non-conductive materials include the same material.

6. The method of claim 2, wherein each of the first and third non-conductive materials is selected from the group consisting of silicon nitride, silicon oxide and silicon carbide.

7. The method of claim 6, wherein the second non-conductive material is different from the first and third non-conductive materials, and the second non-conductive material is selected from the group consisting of silicon nitride, silicon oxide and silicon carbide.

8. The method of claim 1, wherein the second layer has a thickness in a range of about 30 nm to about 60 nm.
